(19) United States
(12) Patent Application Publication
(10) Pub. No.: US 2011/0193067 A1
(43) Pub. Date: Aug. 11, 2011

(54) ORGANIC LIGHT-EMITTING DEVICE INCLUDING BARRIER LAYER INCLUDING SILICON OXIDE LAYER AND SILICON-RICH SILICON NITRIDE LAYER

(75) Inventors: Jae-Seob LEE, Yongin-City (KR); Dong-Un JIN, Yongin-City (KR)

(73) Assignee: SAMSUNG MOBILE DISPLAY CO., LTD., Yongin-City (KR)

(21) Appl. No.: 12/895,315

(22) Filed: Sep. 30, 2010

(30) Foreign Application Priority Data
Feb. 9, 2010 (KR) 10-2010-0012018

(51) Int. Cl. H01L 51/30

(52) U.S. Cl. 257/40; 257/E51.025

(57) ABSTRACT

An organic light-emitting device including a barrier layer that includes a silicon oxide layer and a silicon-rich silicon nitride layer. The organic light-emitting device includes a flexible substrate that includes a barrier layer and plastic films disposed under and over the barrier layer. The barrier layer includes a silicon-rich silicon nitride layer and a silicon oxide layer. The order in which the silicon-rich silicon nitride layer and the silicon oxide layer are stacked is not limited and the silicon oxide layer may be first formed and then the silicon-rich silicon nitride layer may be stacked on the silicon oxide layer. The silicon-rich silicon nitride layer has a refractive index of 1.81 to 1.85.

### CLAIM OF PRIORITY

This application claims the benefit of Korean Patent Application No. 10-2010-0012018, filed on Feb. 9, 2010, in the Korean Intellectual Property Office, the disclosure of which is incorporated herein in its entirety by reference.

### BACKGROUND OF THE INVENTION

1. Field of the Invention

The present invention relates to an organic light-emitting device including a barrier layer that includes a silicon oxide layer and a silicon-rich silicon nitride layer.

2. Description of the Related Art

As flexible flat display devices have recently attracted increasing attention, research is being actively conducted on flexible flat display devices. Flexible flat display devices are manufactured by using a flexible substrate formed of a flexible material such as plastic, and not a glass substrate.

A flat display device includes a thin film transistor (TFT) for controlling the operation of each pixel or generating an electrical signal to be provided to a driving unit. It is necessary to protect the TFT from external impurities. In particular, since an organic TFT, on which research has recently been actively conducted as also on a flexible flat display device, is formed of an organic material that is very vulnerable to external moisture or oxygen, it is necessary to prevent external impurities from penetrating into the organic material.

Since an organic light-emitting device, on which research has also recently been actively conducted in connection with a display unit of a flexible flat display device, includes an electronic light-emitting element, in each pixel, which is formed of an organic material that is very vulnerable to external moisture or oxygen, it is necessary to prevent external impurities from penetrating into the organic material.

A barrier layer, which is used to prevent the penetration of external impurities, may peel off during a process.

### SUMMARY OF THE INVENTION

The present invention provides an organic light-emitting device that may prevent a barrier layer from peeling off.

According to an aspect of the present invention, there is provided an organic light-emitting device including: a substrate; a barrier layer; and an organic electroluminescent layer, wherein the barrier layer includes a silicon oxide layer and a silicon-rich silicon nitride layer.

The silicon-rich silicon nitride layer may have a refractive index ranging from about 1.81 to about 1.85.

The silicon-rich silicon nitride layer may be subject to a stress ranging from about −200 Mpa to about 0 MPa.

The barrier layer may include a plurality of silicon oxide layers and a plurality of silicon-rich silicon nitride layers which are alternately disposed on each other.

The silicon-rich silicon nitride layer may have a thickness ranging from about 20 nm to about 80 nm.

The silicon oxide layer may have a thickness ranging from about 100 nm to about 500 nm.

The barrier layer may have a thickness ranging from about 120 nm to about 2000 nm.

The barrier layer may have a structure in which a silicon-rich silicon nitride layer, a silicon oxide layer, a silicon-rich silicon nitride layer, a silicon oxide layer, a silicon-rich silicon nitride layer, a silicon oxide layer, and a silicon-rich silicon nitride layer are stacked.

The silicon-rich silicon nitride layer may include SiNₓ where “x” ranges from about 1.1 to about 1.3.

The silicon oxide layer may be a silicon-rich silicon oxide layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a flexible substrate included in an organic light-emitting device, according to an embodiment of the present invention;

FIG. 2 is a cross-sectional view of a modification of the flexible substrate of FIG. 1;

FIG. 3 is a cross-sectional view of another modification of the flexible substrate of FIG. 1;

FIG. 4 is a cross-sectional view of another modification of the flexible substrate of FIG. 1;

FIG. 5 is a cross-sectional view of a thin film transistor (TFT) disposed on the flexible substrate FIG. 4, according to an embodiment of the present invention;

FIG. 6 is a cross-sectional view of an organic light-emitting device according an embodiment of the present invention;

FIG. 7 is a transmission electron microscopic (TEM) photograph illustrating whether a barrier layer of Comparative Example 1 peeled off; and

FIG. 8 is a TEM photograph illustrating whether a barrier layer of Example 1 peeled off.

### DETAILED DESCRIPTION OF THE INVENTION

A conventional flexible display panel is manufactured by coating plastic on a glass substrate, depositing a barrier layer on the plastic, forming an oxide thin film transistor (TFT) backplane, performing electroluminescence (EL) evaporation and thin film encapsulation, and detaching a plastic panel from the glass substrate. A plastic substrate used for the conventional flexible display panel has a very high water vapor transmission rate, unlike a glass substrate, and thus reduces the lifetime of an EL unit. In general, glass has a water vapor transmission rate of less than 1E-6 g/m²/day and plastic has a water vapor transmission rate of more than 1E-1 g/m²/day.

Accordingly, in order to protect the EL unit from moisture output from the plastic substrate, a barrier layer is disposed. In general, a barrier layer is formed by alternately depositing SiNₓ (N) and SiO₂ (O) through plasma-enhanced chemical vapour deposition (PECVD) in the form of NONONON where N has a thickness of approximately 50 nm and O has a thickness of approximately 300 nm. A barrier layer generally has a water vapor transmission rate of less than about 1E-3 g/m²/day. If the barrier layer has a total thickness of about 1050 nm and is subject to stress, the glass substrate may warp and the barrier layer may peel off from the glass substrate.

To solve the problems, there is provided an organic light-emitting device including an organic EL unit and a barrier layer that includes a silicon oxide layer and a silicon-rich silicon nitride layer.

The present invention will now be described more fully with reference to the accompanying drawings, in which exemplary embodiments of the invention are shown.

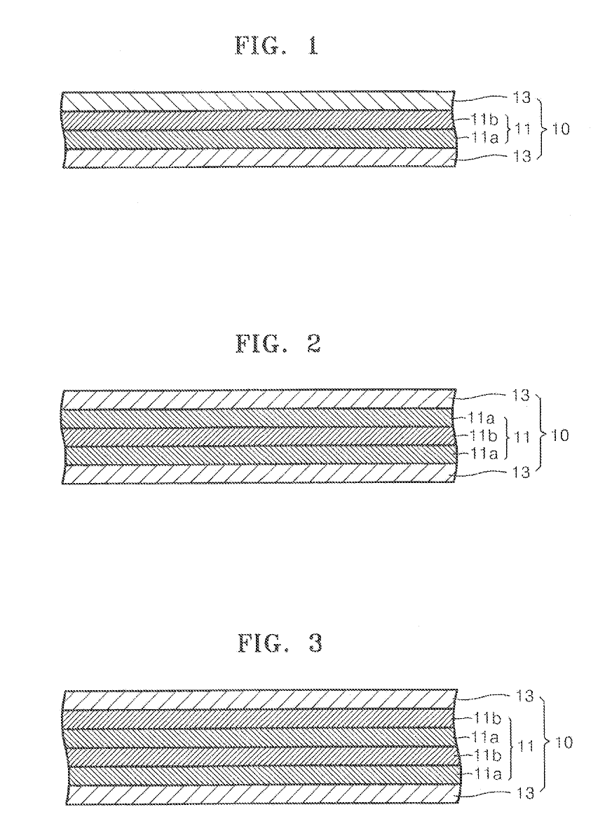

FIG. 1 is a cross-sectional view of a flexible substrate 10 included in an organic light-emitting device, according to an embodiment of the present invention.

Referring to FIG. 1, the flexible substrate 10 includes a barrier layer 11 and plastic films 13 disposed under and over the barrier layer 11. The barrier layer 11 includes a silicon-rich silicon nitride layer 11a and a silicon oxide layer 11b. The order in which the silicon-rich silicon nitride layer 11a and the silicon oxide layer 11b are stacked is not limited to the order shown in FIG. 1, and the silicon oxide layer 11b may be first formed and then the silicon-rich silicon nitride layer 11a may be stacked on the silicon oxide layer 11b.

The silicon-rich silicon nitride layer 11a has a refractive index of 1.81 to 1.85.

When the silicon-rich silicon nitride layer 11a has a refractive index of 1.81 to 1.85, the silicon-rich silicon nitride layer 11a has optimum moisture resistance.

Each of the silicon-rich silicon nitride layer 11a and the silicon oxide layer 11b of the barrier layer 11 may be formed by PECVD or atomic layer deposition (ALD). However, the present invention is not limited thereto, and each of the silicon-rich silicon nitride layer 11a and the silicon oxide layer 11b of the barrier layer 11 may be formed by other methods.

For example, the silicon-rich silicon nitride layer 11a may be manufactured by flowing SiH₄ at a flow rate of about 350 to about 550 sccm, NH₃ at a flow rate of about 1800 to about 2200 sccm, and N₂ at a flow rate of about 9000 to about 11000 sccm. In this case, the silicon-rich silicon nitride layer 11a has a stress of less than about −200 Mpa to about 0 Mpa.

A stress may be calculated by detecting a difference between the warp of a glass substrate when a silicon-rich silicon nitride layer is deposited on the glass substrate to, for example, a thickness of about 200 nm by flowing SiH₄ at a flow rate of about 350 to about 550 sccm, NH₃ at a flow rate of about 1800 to about 2200 sccm, and N₂ at a flow rate of about 9000 to about 11000 sccm and the warp of a glass substrate when a silicon-rich silicon nitride layer is deposited on the glass substrate to a thickness of about 200 nm by flowing SiH₄ at a flow rate of about 100 to about 300 sccm, NH₃ at a flow rate of about 1800 to about 2200 sccm, and N₂ at a flow rate of about 9000 to about 11000 sccm.

The barrier layer 11 may be manufactured by chemical vapor deposition (CVD) or ALD. However, the present invention is not limited thereto, and the barrier layer 11 may be manufactured by other methods.

Since the barrier layer 11 has high surface roughness, if a TFT is formed on the flexible substrate 10 including only the barrier layer 11, throughput is reduced. Accordingly, the plastic films 13 may be disposed under and over the barrier layer 11. The plastic films 13 may be formed by laminating a plastic material on a bottom surface and a top surface of the barrier layer 11 with a hot roll laminator. However, the present invention is not limited thereto, and the plastic films 13 may be formed by other methods. For example, the flexible substrate 10 may be manufactured by sequentially forming the silicon-rich silicon nitride layer 11a and the silicon oxide layer 11b on one of the plastic films 13 in the order stated and then forming the other plastic film 13 on the silicon oxide layer 11b.

The silicon-rich silicon nitride layer 11a of the barrier layer 11 of the flexible substrate 10 reduces water vapor transmission and the silicon oxide layer 11b ensures stress balances.

Although the barrier layer 11 includes one silicon-rich silicon oxide layer and one silicon oxide layer in FIG. 1, the barrier layer 11 may include two silicon-rich silicon nitride layers disposed on both sides of one silicon oxide layer as shown in FIG. 2. Alternatively, two silicon oxide layers may be disposed on both sides of one silicon-rich silicon nitride layer.

Alternatively, the barrier layer 11 may have a structure in which a plurality of the silicon-rich silicon nitride layers 11a and a plurality of the silicon oxide layers 11b are alternately disposed on each other, as shown in FIG. 3.

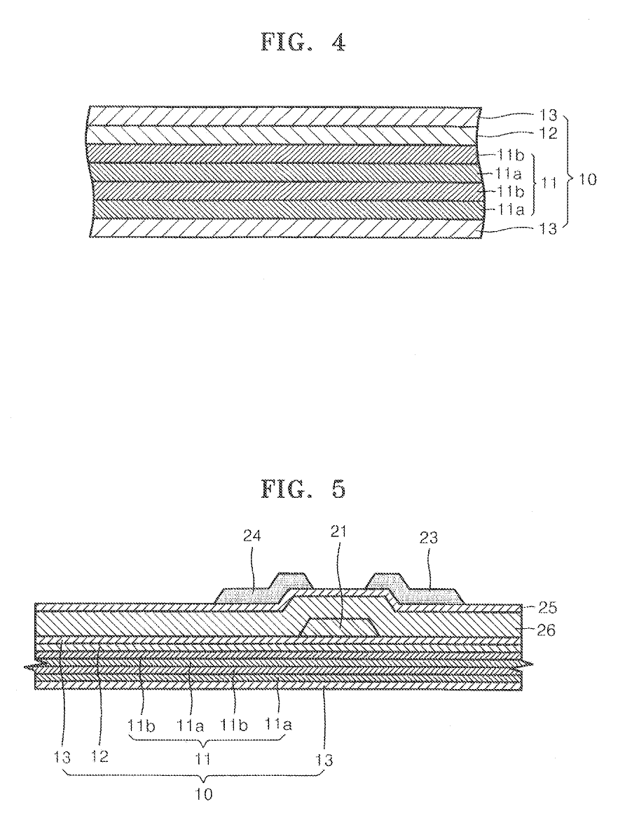

Since the plastic films 13 are disposed under and over the barrier layer 11, as described above, in order to increase an adhesive force between the plastic films 13 and the barrier layer 11, an adhesive layer 12 may be disposed between the barrier layer 11 and the plastic films 13. The position of the adhesive layer 12 is not limited to that shown in FIG. 4, and the adhesive layer 12 may be disposed on at least one of the spaces between the barrier layer 11 and the plastic films 13.

The silicon-rich silicon nitride layer 11a may have a thickness of about 20 nm to about 80 nm, and the silicon oxide layer 11b may have a thickness of about 100 nm to about 500 nm.

If the silicon-rich silicon nitride layer 11a has a thickness of about 20 nm to about 80 nm and the silicon oxide layer 11b has a thickness of about 100 nm to about 500 nm, the silicon-rich silicon nitride layer 11a and the silicon oxide layer 11b may have an optimum moisture resistance and stress balance.

The barrier layer 11 may have a thickness of about 120 nm to about 2000 nm in consideration of a total thickness of the organic light-emitting device, moisture resistance, and warp prevention.

The barrier layer 11 may have a structure in which a silicon-rich silicon nitride layer, a silicon oxide layer, a silicon-rich silicon nitride layer, a silicon oxide layer, a silicon-rich silicon nitride layer, a silicon oxide layer, and a silicon-rich silicon nitride layer are stacked.

The silicon oxide layer 11b may be a silicon-rich silicon oxide layer.

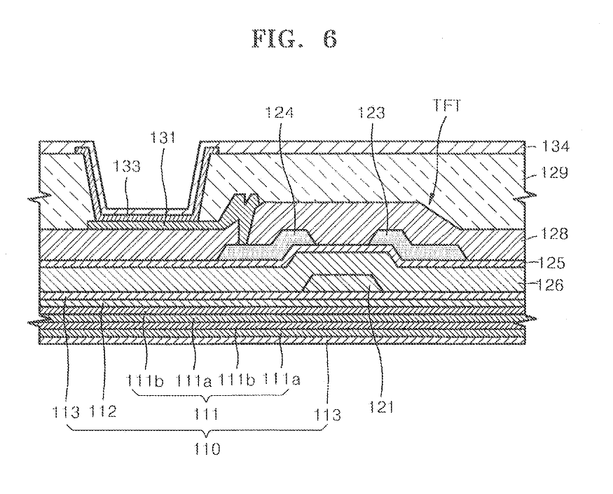

FIG. 5 is a cross-sectional view of a TFT disposed on the flexible substrate 10 of FIG. 4, according to an embodiment of the present invention.

Referring to FIG. 5, the TFT, including a gate electrode 21, a source electrode 23, a drain electrode 24, a semiconductor layer 25, and a gate insulating layer 26, is disposed on the flexible substrate 10, including the adhesive layer 12, of FIG. 4.

Since the TFT, particularly, an organic TFT, is vulnerable to external impurities, such as external moisture or oxygen, as described above, the TFT may be protected by any of the flexible substrates 10 of FIGS. 1 through 4.

FIG. 6 is a cross-sectional view of an organic light-emitting device according to an embodiment of the present invention.

Among various types, the organic light-emitting device of FIG. 6 may be an active matrix (AM) light-emitting display device including an organic TFT.

Each sub-pixel includes at least one organic TFT as shown in FIG. 6. Referring to FIG. 6, an organic TFT is disposed on such a flexible substrate 110 as shown in any of FIGS. 1 through 4. The type of a TFT is not limited to the one shown in FIG. 6, and various TFTs, including a silicon TFT, may be used.

A passivation layer 128 formed of SiO₂ is formed on the organic TFT, and a pixel defining layer 129 formed of acryl, polyimide, or the like is formed on the passivation layer 128. The passivation layer 128 may protect the organic TFT, and planarize a top surface of the organic TFT.

Although not shown, at least one capacitor may be connected to the organic TFT. A circuit including the organic TFT is not limited to the one shown in FIG. 6, and various modifications may be made.

An organic light-emitting element is connected to a drain electrode 124. The organic light-emitting element includes a pixel electrode 131 and a counter electrode 134, which face each other, and an intermediate layer 133 including at least one light-emitting layer and disposed between the pixel electrode 131 and the counter electrode 134. The counter electrode 134 may be modified in various ways, for example, may be shared by a plurality of pixels.

Although the intermediate layer 133 is patterned to correspond to only one sub-pixel in FIG. 6 for convenience of explanation of the construction of a sub-pixel, the intermediate layer 133 may be integrally formed with an intermediate layer of an adjacent to sub-pixel. Alternatively, some of a plurality of the intermediate layers 133 may be formed to respectively correspond to sub-pixels and the remaining ones of the plurality of intermediate layers 133 may be integrally formed with intermediate layers of neighbouring sub-pixels.

The pixel electrode 131 acts as an anode and the counter electrode 134 acts as a cathode. Alternatively, the pixel electrode 131 may act as a cathode and the counter is electrode 134 may act as an anode.

The pixel electrode 131 is a reflective electrode. That is, the flexible substrate 110 includes a barrier layer 111 that includes silicon-rich silicon nitride layers 111a and silicon oxide layers 111b that are alternately stacked. Since the barrier layer 111 is opaque, light generated by the intermediate layer 133 is emitted through the counter electrode 134 away from the flexible substrate 110. Accordingly, the pixel electrode 131 is a reflective electrode and the counter electrode 134 is a transparent electrode.

Accordingly, the pixel electrode 131 may be formed by forming a reflective layer formed of silver (Ag), magnesium (Mg), aluminium (Al), platinum (Pt), lead (Pd), gold (Au), nickel (Ni), neodymium (Nd), iridium (Ir), chromium (Cr), or a compound thereof and forming indium tin oxide (ITO), indium zinc oxide (IZO), zinc oxide (ZnO), or In₂O₃ on the reflective layer. The counter electrode 134, which is a transparent electrode, may be formed by depositing lithium (Li), calcium (Ca), lithium fluoride/calcium (LiF/Ca), lithium fluoride/aluminium (LiF/Al), Al, Mg, or a compound thereof to face the intermediate layer 133, and forming an auxiliary electrode or a bus electrode line formed of a transparent electrode forming material such as ITO, IZO, ZnO, or IN₂O₃.

The intermediate layer 133 disposed between the pixel electrode 131 and the counter electrode 134 may be formed of a low molecular weight organic material or a high molecular weight organic material. If the intermediate layer 133 is formed of a low molecular weight organic material, the intermediate layer 133 may be formed by stacking a hole injection layer (HIL), a hole transport layer (HTL), an organic emission layer (EML), an electron transparent layer (ETL), and an electron injection layer (EIL) in a single structure or complex structure. Examples of the low molecular weight organic material of the intermediate layer 133 may include copper phthalocyanine (CuPc), N,N′-Di(naphthalene-1-yl)-N,N′-diphenyl-benzidine (NPB), and tris-8-hydroxyquinoline aluminum (Alq3). The low molecular weight organic materials are disposed by patterning and are formed by vacuum deposition using masks, as described above.

If the intermediate layer 133 is formed of a high molecular weight organic material, the intermediate layer 133 may have a structure including an HTL and an EML. The HTL may be formed of poly-(2,4)-ethylene-dihydroxy thiophene (PEDOT), and the EML may be formed of a high molecular weight organic material such as poly-phenylenevinylene (PPV) or polyfluorene.

The organic light-emitting element formed on the flexible substrate 110 is sealed by a counter member (not shown). The counter member may be formed of the same glass or plastic material as that of the flexible substrate 110. Alternatively, the counter member may be formed of a metal cap or the like.

Although the organic light-emitting device has been explained, the present invention may be applied to various other flexible display devices.

Although an explanation will be made on the following examples in detail, the present invention is not limited thereto.

### Comparison of Water Vapor Transmission Rate

### Example 1

### SiH₄ 400 sccm, NH₃ 2000 sccm, N₂ 10000 sccm

A barrier layer having a structure in which a silicon-rich silicon nitride layer, a silicon oxide layer, a silicon-rich silicon nitride layer, a silicon oxide layer, a silicon-rich silicon nitride layer, a silicon oxide layer, and a silicon-rich silicon nitride layer were stacked by PECVD was formed on a glass substrate, wherein each silicon-rich silicon nitride layer having a thickness of 50 nm was formed by flowing SiH₄ at a flow rate of 400 scorn, NH₃ at a flow rate of 2000 sccm, and N₂ at a flow rate of 10000 sccm, and each silicon oxide layer having a thickness of 300 nm was formed by flowing SiH₄ at a flow rate of 150 scorn, N₂O at a flow rate of 3000 sccm, and Ar at a flow rate of 4000 sccm.

After performing Fourier transform infrared spectroscopy (FTIR), a ratio of Si to N of each silicon-rich silicon nitride layer was about 1:1.2.

### Example 2

### SiH₄ 500 sccm, NH₃ 2000 sccm, N₂ 10000 sccm

A barrier layer was formed in the same manner as Example 1 except that SiH₄ was flowed at a flow rate of 500 sccm.

### Comparative Example 1

### SiH₄ 100 sccm, NH₃ 2000 sccm, N₂ 10000 sccm

A barrier layer was formed in the same manner as Example 1 except that SiH₄ was flowed at a flow rate of 100 sccm.

### Comparative Example 2

### SiH₄ 200 sccm, NH₃ 2000 sccm, N₂ 10000 sccm

A barrier layer was formed in the same manner as Example 1 except that SiH₄ was flowed at a flow rate of 200 sccm.

Water vapor transmission rates of Examples 1 and 2 and Comparative Examples 1 and 2 are shown in Table 1.

Referring to Table 1, the water vapor transmission rates of the barrier layers of Examples 1 and 2 are similar to those of the barrier layers of Comparative Examples 1 and 2.

TABLE 1

| | Water Vapor Transmission |
|---|---|
| | Rate (WVTR) |
| Example 1 | ≦1E−3 g/m²/day |
| Example 2 | ≦1E−3 g/m²/day |
| Comparative | ≦1E−3 g/m²/day |
| Example 1 | |
| Comparative | ≦1E−3 g/m²/day |
| Example 2 | |

(conditions: WVTR, Mocon test, measurement limit: ≧1E-3 g/m²/day)

Observation of Peeling-Off of Barrier Layer

Whether the barrier layers of Example 1 and Comparative Example 1 peeled off after being kept at room temperature for 2 weeks was observed.

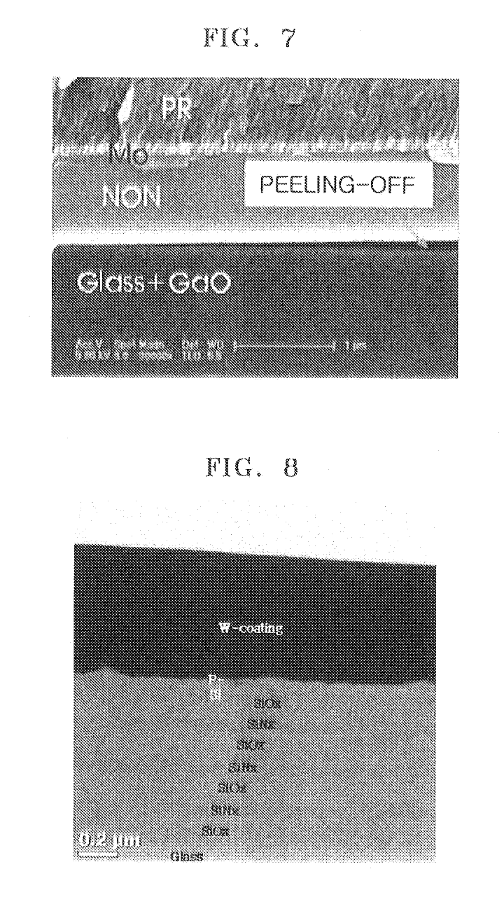

FIG. 7 is a transmission electron microscopic (TEM) photograph illustrating whether the barrier layer of Comparative Example 1 peeled off.

FIG. 8 is a TEM photograph illustrating whether the barrier layer of Example 1 peeled off.

Referring to FIGS. 7 and 8, the barrier layer of Example 1 did not peel off, whereas the barrier layer of Comparative Example 1 peeled off.

### Measurement of Stress of Silicon Nitride Layer

### Example 3

### SiH₄ 400 sccm, NH₃ 2000 sccm, N₂ 10000 sccm

A silicon-rich silicon nitride layer having a thickness of 100 nm was formed by PECVD on a glass substrate by flowing SiH₄ at a flow rate of 400 sccm, NH₃ at a flow rate of 2000 sccm, and N₂ at a flow rate of 10000 sccm.

### Example 4

### SiH₄ 500 sccm, NH₃ 2000 sccm, N₂ 10000 sccm

A silicon-rich silicon nitride layer was formed in the same manner as Example 3 except that SiH₄ was flowed at a flow rate of 500 sccm.

### Comparative Example 3

### SiH₄ 100 sccm, NH₃ 2000 sccm, N₂ 10000 sccm

A silicon nitride layer was formed in the same manner as Example 3 except that SiH₄ was flowed at a flow rate of 100 sccm.

### Comparative Example 4

### SiH₄ 200 sccm, NH₃ 2000 sccm, N₂ 10000 sccm

A silicon nitride layer was formed in the same manner as Example 3 except that SiH₄ was flowed at a flow rate of 200 sccm.

Refractive indexes and stresses of the silicon nitride layers of Examples 3 and 4 and Comparative Examples 3 and 4 are shown in Table 2.

A stress was calculated by measuring the degree of warping of a glass substrate before a silicon nitride layer was deposited, measuring the degree of warping of the glass substrate after the silicon nitride layer was deposited on the silicon substrate to a thickness of 100 nm, and calculating a difference in the radius of curvature by using, for example, the Stoney equation.

$$\begin{matrix}{σ}_{ii , r} = {σ}_{ii , int} + {σ}_{ii , th} \\ = {σ}_{ii , int} + \frac{- {E}_{f}}{1 - {v}_{f}} ( {α}_{sub} - {α}_{film} ) Δ T \\ = - ( \frac{1}{R} - \frac{1}{{R}_{0}} ) \frac{{E}_{sub}}{1 - {v}_{sub}} \cdot \frac{{t}_{sub}^{2}}{6 {t}_{film}}\end{matrix}$$

R: the radius of curvature of a glass substrate after deposition

Rₒ: the radius of curvature of the glass substrate before deposition

σ: a stress of a film

E_{f}: a Young's modulus of the film

E_{sub}: a Young's modulus of the glass substrate

v_{f}: a Poisson's ratio of the film

v_{sub}: a Poisson's ratio of the glass substrate

t_{film}: a thickness of the film

t_{sub}: a thickness of the glass substrate

α_{film}: a thermal expansion coefficient of the film

α_{sub}: a thermal expansion coefficient of the glass substrate

σ_{ii,r}: residual stress of film in biaxial direction

σ_{ii, int}: intrinsic stress of film in biaxial direction, which refers to the stress produced by a change of film density during or after deposition.

σ_{ii, th}: thermal stress of film in biaxial direction, which is due to differences in the thermal expansion coefficients of the film and substrate.

Referring to Table 2, the stresses of the silicon-rich silicon nitride layers of Examples 3 and 4 are less than the stresses of the silicon nitride layers of Comparative Examples 3 and 4.

TABLE 2

| | Refractive index | Stress (Mpa) |
|---|---|---|
| Example 3 | 1.82 | −200 |
| Example 4 | 1.83 | −120 |
| Comparative Example 3 | 1.80 | −450 |
| Comparative Example 4 | 1.79 | −550 |

As described above, according to the present invention, since a stress-free barrier layer is used, peeling-off and glass warping are prevented during a process of forming a backplane, thereby improving throughput.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. An organic light-emitting device comprising:
a substrate;
a barrier layer; and
an organic electroluminescent layer,
wherein the barrier layer comprises a silicon oxide layer and a silicon nitride layer comprising SiNₓ, where x ranges from about 1.1 to about 1.3.

2. The organic light-emitting device of claim 1, wherein the silicon nitride layer has a refractive index ranging from about 1.81 to about 1.85.

3. The organic light-emitting device of claim 1, wherein the silicon nitride layer has a stress ranging from about −200 Mpa to about 0 MPa.

4. The organic light-emitting device of claim 1, wherein the barrier layer comprises a plurality of silicon oxide layers and a plurality of silicon nitride layers which are alternately disposed on each other.

5. The organic light-emitting device of claim 1, wherein the silicon nitride layer has a thickness ranging from about 20 nm to about 80 nm.

6. The organic light-emitting device of claim 1, wherein the silicon oxide layer has a thickness ranging from about 100 nm to about 500 nm.

7. The organic light-emitting device of claim 1, wherein the barrier layer has a thickness ranging from about 120 nm to about 2000 nm.

8. The organic light-emitting device of claim 1, wherein the barrier layer has a structure comprising a silicon nitride layer, a silicon oxide layer, a silicon nitride layer, a silicon oxide layer, a silicon nitride layer, a silicon oxide layer, and a silicon nitride layer alternately stacked, wherein each of the silicon nitride layers comprise SiNₓ, where x ranges from about 1.1 to about 1.3.

9. The organic light-emitting device of claim 1, wherein the silicon oxide layer is a silicon-rich silicon oxide layer.

10. The organic light-emitting device of claim 8, wherein the silicon oxide layer is a silicon-rich silicon oxide layer.
